(19) United States
(12) Patent Application Publication
(10) Pub. No.: US 2021/0126592 A1
(43) Pub. Date: Apr. 29, 2021

(54) IMPEDANCE MATCHING CIRCUIT AND METHOD

(71) Applicant: SHAANXI REACTOR MICROELECTRONICS CO., LTD, Xi'an (CN)

(72) Inventors: Junfeng MA, XI'AN (CN); Qin XIA, XI'AN (CN)

(73) Assignee: SHAANXI REACTOR MICROELECTRONICS CO., LTD

(21) Appl. No.: 17/060,418

(22) Filed: Oct. 1, 2020

Related U.S. Application Data
(63) Continuation of application No. PCT/CN2020/092346, filed on May 26, 2020.

(30) Foreign Application Priority Data
Oct. 27, 2019 (CN) 201911027182.0

(51) Int. Cl. H03F 1/56; H03F 3/21

(52) U.S. Cl. CPC H03F 1/56; H03F 3/21; H03F 2200/387; H03F 2200/451; H03F 2200/105

(57) ABSTRACT

The present invention discloses an impedance matching circuit and method. The circuit is applied to a power supply circuit of an envelope tracking radio frequency power amplifier. An envelope tracking power supply is connected with a radio frequency power amplifier through a first matching circuit. The envelope tracking radio frequency power amplifier obtains the optimal efficiency by performing matching according to an optimal efficiency load impedance of the envelope tracking power supply and a conjugate impedance of an optimal efficiency load impedance of the radio frequency power amplifier.

### CROSS REFERENCE TO RELATED APPLICATIONS

This application is a continuation of International Patent Application No. PCT/CN2020/092346 with a filing date of May 26, 2020, designating the United States, now pending, and further claims priority to Chinese Patent Application No. 201911027182.0 filed on Oct. 27, 2019, the entire content of which is incorporated herein by reference.

### TECHNICAL FIELD

The present invention relates to wireless communication field and more particularly to an impedance matching circuit and method.

### BACKGROUND

A radio frequency power amplifier is an important part of different wireless transmitters. In a pre-circuit of the transmitter, a radio frequency signal power generated by a modulation oscillator circuit is amplified to obtain a sufficient radio frequency power and feed it to an antenna for radiation. Therefore, the radio frequency power amplifier is a very important module in the modern communication systems. Especially, in the 5G communication base stations, high efficiency radio frequency power amplifiers determine the 5G base station specifications, entire machine power consumption, subsequent construction and operation costs.

Impedance matching is an effective way of improving the efficiency of a radio frequency power amplifier, in which all high frequency signals are transmitted to a load point without any signals reflected back to a source point so as to improve the transmission efficiency. A traditional impedance matching technology is to design an impedance matching network to enable a signal source impedance and a load impedance to be conjugately matched so as to realize transmission with the highest transmission power.

Through technical study, the inventor found that a new-generation communication technology employs combination of envelope tracking technology and radio frequency power amplifier, and performing conjugate matching of the source impedance and the load impedance of the radio frequency power amplifier only cannot solve the power output problem satisfactorily.

Thus, how to improve the power output efficiency of the envelope tracking radio frequency power amplifier becomes an urgent technical problem to be solved by the persons skilled in the art.

### SUMMARY

The present invention provides an impedance matching circuit to solve the problem that the impedance matching power output efficiency of the radio frequency power amplifiers is low so that the envelope tracking radio frequency power amplifiers cannot achieve a qualified power output efficiency in the prior art. The circuit is applied to a power supply circuit of the envelope tracking radio frequency power amplifier and includes an envelope tracking power supply, a radio frequency power amplifier, a first matching circuit, and a blocking capacitor.

The envelope tracking power supply is configured to perform envelope tracking processing for an input signal and supply electric energy to the radio frequency power amplifier.

The first matching circuit includes a first matching unit and a capacitor.

An input end of the first matching unit is connected with an output end of the envelope tracking power supply respectively, the output end is connected with one end of the blocking capacitor, the first matching circuit is located between the radio frequency power amplifier and the blocking capacitor. An optimal efficiency of the envelope tracking radio frequency power amplifier is obtained by performing impedance matching according to an optimal efficiency load impedance of the envelope tracking power supply and a conjugate impedance of an optimal efficiency load impedance of the radio frequency power amplifier; and/or, the optimal efficiency of the envelope tracking radio frequency power amplifier is obtained by matching the optimal efficiency load impedance of the envelope tracking power supply according to a conjugate impedance of a load impedance value of the radio frequency power amplifier.

Preferably, the impedance matching circuit further includes a third superimposing circuit.

The third superimposing circuit is configured to superimpose a fundamental wave and a higher harmonic wave in a circuit to output a superimposed signal.

Preferably, the impedance matching circuit further includes a second matching circuit including a second matching unit and a capacitor.

The second matching circuit is configured to obtain a designated load impedance by performing impedance matching according to the optimal efficiency load impedance of the envelope tracking power supply.

Preferably, an input end of the second matching circuit is connected with the other end of the blocking capacitor to form a matching network with the blocking capacitor.

The matching network is configured to obtain the designated load impedance by performing impedance matching according to the obtained optimal efficiency load impedance of the envelope tracking power supply.

Preferably, the first matching unit includes microstrip lines or coplanar waveguides of different specifications.

The second matching unit further includes microstrip lines or coplanar waveguides of different specifications.

A length of the microstrip line or the coplanar waveguide depends on requirements of matching the optimal efficiency load impedance of the envelope tracking power supply to the designated load impedance.

Preferably, the third superimposing circuit includes microstrip lines or coplanar waveguides of different lengths, where the length of the microstrip line or the coplanar waveguide corresponds to a frequency of an output power of the radio frequency power amplifier.

Correspondingly, the present invention further provides an impedance matching method, applied to a power supply circuit of an envelope tracking radio frequency power amplifier. The method includes:

obtaining an optimal efficiency of the envelope tracking radio frequency power amplifier by performing impedance matching according to an optimal efficiency load impedance of an envelope tracking power supply and a conjugate impedance of an optimal efficiency load impedance of an radio frequency power amplifier; and

obtaining a designated load impedance by performing impedance matching according to the obtained optimal efficiency load impedance of the envelope tracking power supply.

Preferably, after the designated load impedance is obtained, the method further includes:

superimposing a higher harmonic wave to a fundamental wave to output a superimposed signal.

Preferably, before obtaining the optimal efficiency of the envelope tracking radio frequency power amplifier by performing impedance matching according to the optimal efficiency load impedance of the envelope tracking power supply and the conjugate impedance of the optimal efficiency load impedance of the radio frequency power amplifier, the method further includes:

obtaining the optimal efficiency load impedance of the envelope tracking power supply and/or the conjugate impedance of the optimal efficiency load impedance of the radio frequency power amplifier according to the characteristics of the envelope tracking power supply and/or the radio frequency power amplifier.

Preferably, the method of calculating the optimal efficiency of the envelope tracking radio frequency power amplifier and the designated load impedance includes computer simulation, Smith chart calculation and old experiences.

Compared with the prior art, the present invention has the following beneficial effects.

The present invention discloses an impedance matching circuit and method. The circuit may be applied to the power supply circuit of the envelope tacking radio frequency power amplifier to connect the envelope tracking power supply with the radio frequency power amplifier through the first matching circuit. Matching is performed based on the optimal efficiency load impedance of the envelope tracking power supply and the conjugate impedance of the optimal efficiency load impedance of the radio frequency power amplifier so that the envelope tracking radio frequency power amplifier obtains the optimal efficiency. By superimposing the higher harmonic wave (second-order harmonic wave or third-order harmonic wave) and the fundamental wave in the circuit, the output power of the circuit is further improved, thereby meeting development requirements of signal transmission technology.

### BRIEF DESCRIPTION OF THE DRAWINGS

To more clearly describe the technical solutions of the embodiments of the present invention, the accompanying drawings involved in the descriptions of the embodiments of the present invention will be briefly introduced below. Apparently, the accompanying drawings described below are merely some embodiments of the present invention. Other accompanying drawings may also be obtained by those skilled in the prior art based on these accompanying drawings without paying creative work.

FIG. 1 is a structural schematic diagram of an impedance matching circuit according to an embodiment of the present invention.

FIG. 2 is a structural schematic diagram of an impedance matching circuit according to another embodiment of the present invention.

FIG. 3 is a structural schematic diagram of an impedance matching circuit according to still another embodiment of the present invention.

FIG. 4 is a structural schematic diagram of a third superimposing circuit according to an embodiment of the present invention.

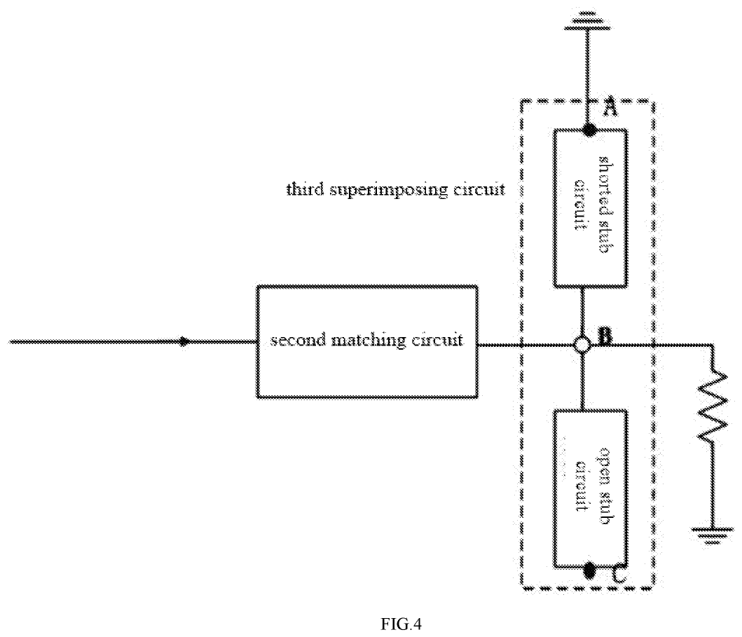

FIG. 5 is a flowchart of an impedance matching method according to an embodiment of the present invention.

### DETAILED DESCRIPTION OF THE EMBODIMENTS

The technical solutions of the embodiments of the present invention will be clearly and fully described below in combination with the accompanying drawings of the embodiments of the present invention. Apparently, these embodiments described herein are merely some embodiments of the present invention rather than all embodiments. Other embodiments obtained by those skilled in the art based on these embodiments of the present invention without paying creative work shall all fall within the scope of protection of the present invention.

As described in the background, the impedance matching power output efficiency of the radio frequency power amplifier in the prior art is low so that the envelope tracking radio frequency power amplifier cannot achieve a qualified power output efficiency.

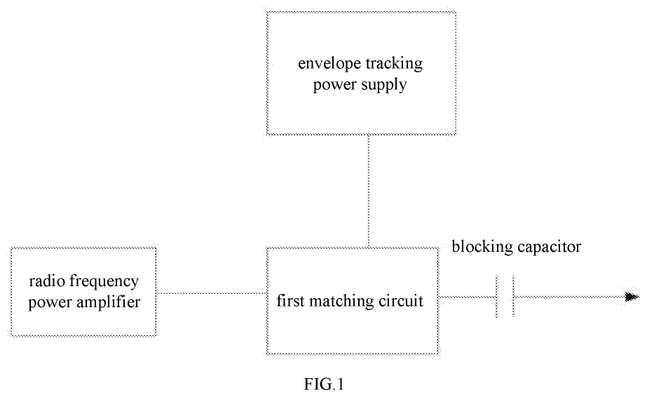

To solve the above problems, an embodiment of the present invention provides an impedance matching circuit applied to a power supply circuit of an envelope tracking radio frequency power amplifier. FIG. 1 is a structural schematic diagram of an impedance matching circuit according to an embodiment of the present invention. The impedance matching circuit includes an envelope tracking power supply, a radio frequency power amplifier, a first matching circuit, and a blocking capacitor.

The envelope tracking power supply is configured to amplify an input envelope signal and supply voltage and current to the radio frequency power amplifier.

The first matching circuit includes a first matching unit and a capacitor.

An input end of the first matching unit is connected with an output end of the envelope tracking power supply respectively, the output end is connected with one end of the blocking capacitor, the first matching circuit is located between the radio frequency power amplifier and the blocking capacitor. An optimal efficiency of the envelope tracking radio frequency power amplifier is obtained by performing impedance matching according to an optimal efficiency load impedance of the envelope tracking power supply and a conjugate impedance of an optimal efficiency load impedance of the radio frequency power amplifier; and/or, the optimal efficiency of the envelope tracking radio frequency power amplifier is obtained by matching the optimal efficiency load impedance of the envelope tracking power supply according to a conjugate impedance of a load impedance value of the radio frequency power amplifier.

Specifically, for a circuit adopting the envelope tracking radio frequency power amplifier, its excitation source impedance is generated by matching of the optimal efficiency load impedance of the envelope tracking power supply and the conjugate impedance of the optimal efficiency load impedance of the radio frequency power amplifier. If matching is performed only for the conjugate impedance of the optimal efficiency load impedance of the radio frequency power amplifier, mismatching will occur, that is, an excitation source will not obtain the highest efficiency or the largest power output. Thus, in the circuit adopting the envelope tracking radio frequency power amplifier, it is necessary to perform conjugate matching for the optimal efficiency load impedance of the envelope tracking power supply and the load impedance of the power amplifier. The envelope tracking power supply and the radio frequency power amplifier are connected through the first matching circuit, the first matching circuit is located between the radio frequency power amplifier and the blocking capacitor, and the first matching circuit includes a first matching unit and a capacitor. In this case, the optimal efficiency of the envelope tracking radio frequency power amplifier is obtained by performing impedance matching according to the optimal efficiency load impedance of the envelope tracking power supply and the conjugate impedance of the optimal efficiency load impedance of the radio frequency power amplifier, and/or, the optimal efficiency of the envelope tracking radio frequency power amplifier is obtained by matching the optimal efficiency load impedance of the envelope tracking power supply according to the conjugate impedance of the load impedance value of the radio frequency power amplifier.

To further improve the efficiency of the envelope tracking radio frequency power amplifier, a preferred embodiment of the present invention further includes a third superimposing circuit.

The third superimposing circuit is configured to superimpose a fundamental wave and a higher harmonic wave (a second-order harmonic wave or a third-order harmonic wave) in the circuit to output a superimposed signal.

Specifically, to improve the output power of the radio frequency power amplifier, it is required to maximize the power output of the fundamental wave and minimize the power output of the second-order harmonic wave or other multi-order harmonic wave. By outputting the superimposed signal by superimposing the fundamental wave and the higher harmonic wave in the third superimposing circuit, the efficiency of the envelope tracking radio frequency power amplifier is further improved.

To transmit all optimal efficiency signals to a load, a preferred embodiment of the present invention further includes a second matching circuit including a second matching unit and a capacitor.

The second matching circuit is configured to obtain a designated load impedance by performing impedance matching according to the optimal efficiency load impedance of the envelope tracking power supply.

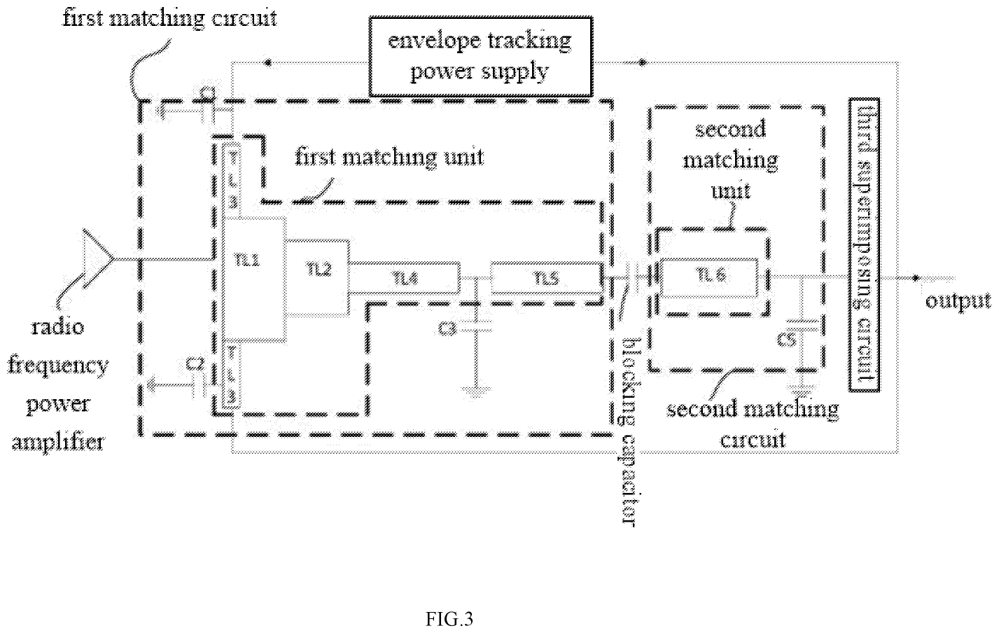

Specifically, impedance matching is performed for the conjugate impedance of the optimal efficiency load impedance of the radio frequency power amplifier and/or the optimal efficiency load impedance of the envelope tracking power supply to obtain the designated load impedance, i.e., 50Ω or 75Ω required by the industrial standard. In this way, reflection of the signals of the radio frequency power amplifier during transmission is reduced, and the signal transmission efficiency is improved based on the optimal efficiency. Further, in a specific application scenario of the present invention, the blocking capacitor shown in FIG. 3 is only used for isolating the first matching circuit from the second matching circuit without impedance matching function.

To further transmit all optimal efficiency signals to the load, the input end of the second matching circuit is connected with the other end of the blocking capacitor to form a matching network with the blocking capacitor in a preferred embodiment of the present invention.

The matching network is used to obtain the designated load impedance by performing impedance matching according to the obtained optimal efficiency load impedance of the envelope tracking power supply.

As described above, the matching network formed by connecting the second matching circuit with the blocking capacitor includes a blocking capacitor. The blocking capacitor participates in impedance matching so that the designated load impedance is obtained by performing impedance matching for the conjugate impedance of the optimal efficiency load impedance of the radio frequency power amplifier and/or the optimal efficiency load impedance of the envelope tracking power supply, thereby further transmitting power signals all to the load.

To satisfy different load impedance needs, the first matching unit includes microstrip lines or coplanar waveguides of different specifications in a preferred embodiment of the present invention.

The second matching unit further includes microstrip lines or coplanar waveguides of different specifications.

The length of the microstrip line or the coplanar waveguide depends on the requirements of matching the optimal efficiency load impedance of the envelope tracking power supply to the designated load impedance.

As described above, the first matching circuit and the second matching circuit include microstrip lines or coplanar waveguides of different specifications and a capacitor respectively. In a specific application scenario of the present invention, the specifications of the microstrip lines or coplanar waveguides and the number and parameters of the capacitors in the first matching circuit are related to the characteristics of the optimal efficiency load impedances of the envelope tracking power supply and the radio frequency power amplifier to be subjected to impedance matching as needed. The second matching circuit is used to match the optimal efficiency load impedance of the envelope tracking power supply to the designated 50Ω or 75Ω required by the industrial standard. Therefore, the specifications of the microstrip lines or coplanar waveguides and the number and parameters of the capacitors in the circuit correspond to the characteristics of the optimal efficiency load impedance of the envelope tracking power supply to be subjected to impedance matching as needed.

To match with the output power of the radio frequency power amplifier, the third superimposing circuit includes microstrip lines or coplanar waveguides of different lengths in a preferred embodiment of the present invention. The length of the microstrip line or the coplanar waveguide corresponds to the frequency of the output power of the radio frequency power amplifier.

In the above technical solution, the envelope tracking power supply is connected with the radio frequency power amplifier through the first matching circuit, and matching is performed based on the optimal efficiency load impedance of the envelope tracking power supply and the conjugate impedance of the optimal efficiency load impedance of the radio frequency power amplifier, so that the envelope tracking radio frequency power amplifier obtains the optimal efficiency. By superimposing the fundamental wave and other higher harmonic wave (second-order harmonic wave or third-order harmonic wave), the output power of the circuit is further improved, thereby satisfying the development requirements of signal transmission technology.

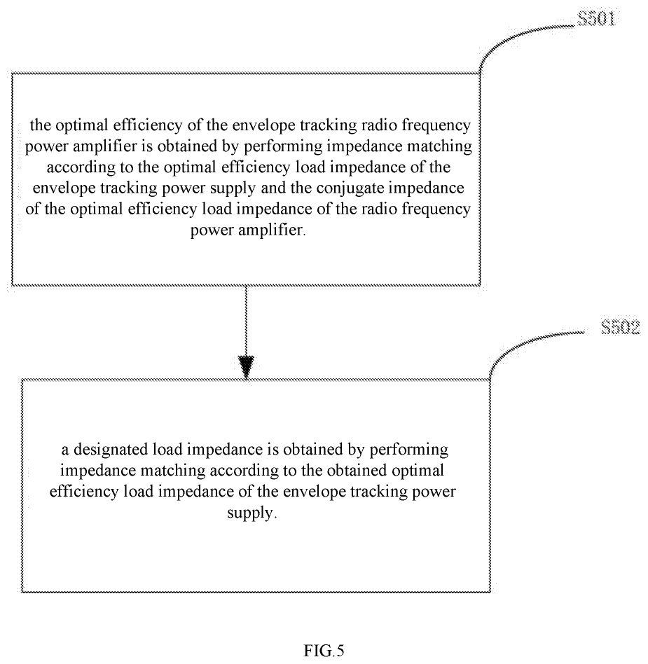

To realize the above technical purpose, an embodiment of the present invention further provides an impedance matching method. In this method, matching is performed for an optimal efficiency load impedance of an envelope tracking power supply and a conjugate impedance of an optimal efficiency load impedance of a radio frequency power amplifier, so that the envelope tracking radio frequency power amplifier can obtain the optimal efficiency and the optimal efficiency load impedance of the envelope tracking power supply. The method includes the following steps as shown in FIG. 5.

At step S501, the optimal efficiency of the envelope tracking radio frequency power amplifier is obtained by performing impedance matching according to the optimal efficiency load impedance of the envelope tracking power supply and the conjugate impedance of the optimal efficiency load impedance of the radio frequency power amplifier.

Specifically, for a circuit adopting the envelope tracking radio frequency power amplifier, its excitation source impedance is generated by matching of the optimal efficiency load impedance of the envelope tracking power supply and the conjugate impedance of the optimal efficiency load impedance of the radio frequency power amplifier. If matching is only performed for the conjugate impedance of the optimal efficiency load impedance of the radio frequency power amplifier, mismatching will occur, that is, the excitation source will not obtain the highest efficiency and the largest power output. Thus, in a circuit adopting the envelope tracking radio frequency power amplifier, it is necessary to perform conjugate matching for the load impedance of the envelope tracking power supply and the load impedance of the power amplifier to obtain the optimal efficiency of the envelope tracking radio frequency power amplifier.

To accurately obtain the optimal efficiency of the envelope tracking radio frequency power amplifier, before the optimal efficiency of the envelope tracking radio frequency power amplifier is obtained by performing impedance matching according to the optimal efficiency load impedance of the envelope tracking power supply and the conjugate impedance of the optimal efficiency load impedance of the radio frequency power amplifier, a preferred embodiment of the present invention further includes:

obtaining the optimal efficiency load impedance of the envelope tracking power supply and/or the conjugate impedance of the optimal efficiency load impedance of the radio frequency power amplifier according to the characteristics of the envelope tracking power supply and/or the radio frequency power amplifier.

As described above, since it is required to determine the optimal efficiency of the envelope tracking radio frequency power amplifier based on the conjugate impedance, the optimal efficiency load impedance of the envelope tracking power supply and/or the conjugate impedance of the optimal efficiency load impedance of the radio frequency power amplifier are firstly obtained according to the characteristics of the envelope tracking power supply and/or the radio frequency power amplifier.

At step S502, a designated load impedance is obtained by performing impedance matching according to the obtained optimal efficiency load impedance of the envelope tracking power supply.

To transmit all optimal efficiency signals to the load, the designated load impedance is obtained by performing impedance matching according to the obtained optimal efficiency load impedance of the envelope tracking power supply.

To further improve the efficiency of the envelope tracking radio frequency power amplifier, an embodiment of the present invention further includes the following before the designated load impedance is obtained:

superimposing the higher harmonic wave to the fundamental wave to output a superimposed signal.

Specifically, to improve the output power of the radio frequency power amplifier, it is required to maximize the output power of fundamental wave and minimize the output efficiency of the second-order harmonic wave or other multi-order harmonic waves. Thus, after the designated load impedance is obtained, other higher harmonic waves are superimposed to the fundamental wave to output a superimposed signal.

It is noted that the solutions of the above preferred embodiments are merely a specific implementation of the present invention and other manners of further improving the efficiency of the envelope tracking radio frequency power amplifier shall all fall within the scope of protection of the present invention.

To accurately obtain the optimal efficiency and the designated load impedance, the method of calculating the optimal efficiency of the envelope tracking radio frequency power amplifier and the designated load impedance includes computer simulation, Smith chart calculation and old experiences in a preferred embodiment of the present invention.

Those skilled in the art may select other calculation methods flexibly based on actual requirements, which does not affect the scope of protection of the present invention.

In the above technical solution, in a power supply circuit adopting the envelope tracking radio frequency power amplifier, the optimal efficiency of the envelope tracking radio frequency power amplifier may be obtained by performing impedance matching according to the optimal efficiency load impedance of the envelope tracking power supply and the conjugate impedance of the optimal efficiency load impedance of the radio frequency power amplifier; and the designated load impedance may be obtained by performing impedance matching according to the obtained optimal efficiency load impedance of the envelope tracking power supply. In this way, the envelope tracking radio frequency power amplifier obtains the optimal efficiency. By superimposing the fundamental wave and the higher harmonic wave in a circuit, the output power and the efficiency of the circuit are further improved, thereby satisfying the development requirements of signal transmission technology.

To further set forth the technical concept of the present invention, the technical solution of the present invention will be described in combination with a specific application scenario.

High efficient signal communication is the trend of development in signal transmission field and especially in the new generation wireless communication field. The present invention provides an impedance matching circuit. The envelope tracking power supply is connected with the radio frequency power amplifier through the first matching circuit and matching is performed for the optimal efficiency load impedance of the envelope tracking power supply and the conjugate impedance of the optimal efficiency load impedance of the radio frequency power amplifier so that the envelope tracking radio frequency power amplifier obtains the optimal efficiency.

The impedance matching is to enable the load impedance and the excitation source impedance to be mutually matched and thus the excitation source obtains the highest output efficiency, i.e. the largest output power. Specifically, for a circuit adopting the envelope tracking radio frequency power amplifier, its excitation source impedance is generated by matching of the optimal efficiency load impedance of the envelope tracking power supply and the conjugate impedance of the optimal efficiency load impedance of the radio frequency power amplifier. If matching is performed only for the conjugate impedance of the optimal efficiency load impedance of the radio frequency power amplifier to enable the circuit to obtain industrial standard 50Ω or 75Ω, mismatching will occur, that is, an excitation source will not obtain the highest efficiency or the largest power output. Thus, in the circuit adopting the envelope tracking radio frequency power amplifier, it is necessary to perform conjugate matching for the optimal efficiency load impedance of the envelope tracking power supply and the load impedance of the power amplifier. When the optimal efficiency load impedance of the envelope tracking power supply and the conjugate impedance of the optimal efficiency load impedance of the radio frequency power amplifier are matched, the circuit will obtain the optimal efficiency and output the largest power under the optimal efficiency, thereby further improving the efficiency of the envelope tracking radio frequency power amplifier.

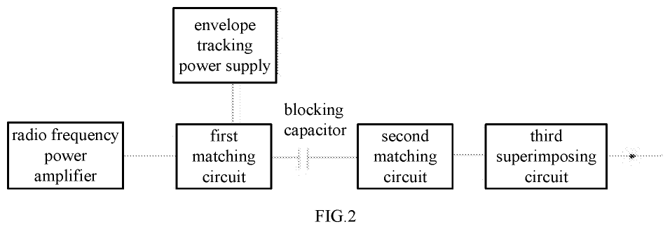

FIG. 2 is a structural schematic diagram of an impedance matching circuit. The circuit includes an envelope tracking power supply, a radio frequency power amplifier, a first matching circuit, a blocking capacitor, a second matching circuit and a third superimposing circuit. The envelope tracking power supply is used to perform envelope tracking processing for the input signal and supply electric energy to the power amplifier. An input end of the first matching unit are connected with an output end of the envelope tracking power supply respectively, the output end is connected with one end of the blocking capacitor, the first matching circuit is located between the radio frequency power amplifier and the blocking capacitor. An optimal efficiency of the envelope tracking radio frequency power amplifier is obtained by performing impedance matching according to an optimal efficiency load impedance of the envelope tracking power supply and a conjugate impedance of an optimal efficiency load impedance of the radio frequency power amplifier; and/or, the optimal efficiency of the envelope tracking radio frequency power amplifier is obtained by matching the optimal efficiency load impedance of the envelope tracking power supply according to a conjugate impedance of a load impedance value of the radio frequency power amplifier.

The first matching circuit is connected with the envelope tracking power supply and located between the radio frequency power amplifier and the blocking capacitor with a purpose of matching the conjugate impedance of the optimal efficiency load impedance of the radio frequency power amplifier to the optimal efficiency load impedance of the envelope tracking power supply so as to enable the envelope tracking radio frequency power amplifier to have the highest output efficiency. The efficiency of the envelope tracking radio frequency power amplifier can be improved by the first matching circuit, which is different from the fact that the output efficiency of the radio frequency power amplifier is improved only by matching the conjugate impedance of the optimal efficiency load impedance of the radio frequency power amplifier to the designated load impedance, i.e. 50Ω or 75Ω required by the industrial standard in the prior art. The prior art can be only applied to the circuit of the radio frequency power amplifier not containing the envelope tracking power supply with a purpose of transmitting signals of the radio frequency power amplifier to the load without a large quantity of signals reflected. The impedance matching circuit in the present invention is used to solve not only the problem of signal transmission of the radio frequency power amplifier but also the problem of output efficiency of the envelope tracking radio frequency power amplifier. That is, the optimal efficiency is obtained by the first matching circuit, the optimal efficiency signals are transmitted to the load without reflection through the second matching circuit and the efficiency of the envelope tracking radio frequency power amplifier is further improved through the third superimposing circuit, thereby better satisfying the signal transmission requirements of high Peak-to-Average Power Ratio, large bandwidth and high efficiency.

In the above embodiments of the present invention, the optimal efficiency of the envelope tracking radio frequency power amplifier can be obtained. But how to transmit all the optimal efficiency signals to the load is also a problem to be considered by the present invention. FIG. 3 is a structural schematic diagram of an impedance matching circuit according to another embodiment of the present invention. The impedance matching circuit includes an envelope tracking power supply, a radio frequency power amplifier, a first matching circuit, a blocking capacitor, a second matching circuit and a third superimposing circuit. The first matching circuit includes a first matching unit and a capacitor, and the second matching circuit includes a second matching unit and a capacitor. Impedance matching is performed for the conjugate impedance of the optimal efficiency load impedance of the radio frequency power amplifier and/or the optimal efficiency load impedance of the envelope tracking power supply by using the matching network formed by the second matching circuit and the blocking capacitor to obtain the designated load impedance, i.e. 50Ω or 75Ω required by industrial standard. In this way, reflection of signals of the radio frequency power amplifier during transmission is reduced and the signal transmission efficiency is improved based on the optimal efficiency.

In a specific application scenario of the present invention, the second matching circuit may also perform impedance matching without including the blocking capacitor. The second matching circuit performs impedance matching according to the optimal efficiency load impedance of the envelope tracking power supply to obtain the designated load impedance. At this time, the blocking capacitor is used only to isolate the first matching circuit from the second matching circuit without impedance matching function.

The first matching circuit and the second matching circuit each include microstrip lines or coplanar waveguides of different specifications and a capacitor. The first matching circuit is used to obtain the optimal efficiency. Since the first matching circuit is affected by different optimal efficiency load impedances of the envelope tracking power supply and different conjugate impedances of the optimal efficiency load impedances of the radio frequency power amplifier, the first matching circuit needs the microstrip lines or coplanar waveguides of different specifications to meet the requirements of different load impedances, that is, the specifications of the microstrip lines or coplanar waveguides and the number and parameters of the capacitors in the first matching circuit are related to the characteristics of the optimal efficiency load impedances of the envelope tracking power supply and the radio frequency power amplifier to be subjected to impedance matching.

The second matching circuit is used to match the optimal efficiency load impedance of the envelope tracking power supply to the designated 50Ω or 75Ω required by industrial standard. Thus, the specifications of the microstrip lines and the number and parameters of the capacitors in the circuit correspond to the characteristics of the optimal efficiency load impedance of the envelope tracking power supply to be subjected to impedance matching.

Those skilled in the art may obtain the optimal efficiency and the designated load impedance by computer simulation, Smith chart calculation and old experiences and the like.

To further improve the efficiency of the envelope tracking radio frequency power amplifier, as shown in FIG. 3, a third superimposing circuit including a shorted stub circuit and an open stub circuit connected in parallel is designed in the circuit of the present invention. Further, input ends of the shorted stub circuit and the open stub circuit are both connected with the output end of the second matching circuit to superimpose the fundamental wave and the higher harmonic wave in the circuit and output a superimposed signal.

To improve the output power of the radio frequency power amplifier, it is required to maximize the power output of the fundamental wave f0 and minimize the power output of the second-order harmonic wave or other higher harmonic waves. But, minimizing the output power of the second-order harmonic wave or other multi-order harmonic waves requires that a harmonic load is shorted, open or is pure reactance. In an actual application, the feasibility of requiring the load to be pure reactance is difficult to reach while it is an effective way to perform circuit designing in the aspect that the harmonic load is shorted and open. Therefore, to improve the output efficiency of the radio frequency power amplifier, it is feasible to design the shorted stub circuit and the open stub circuit connected in parallel.

Descriptions are made with the second-order harmonic wave 2f0 as an example. The shorted stub circuit includes a microstrip line or a coplanar waveguide, and the length of the microstrip line or the coplanar waveguide corresponds to the frequency of the output power of the radio frequency power amplifier, that is, to a wavelength λ, of the fundamental wave. Thus, the length of the microstrip line or coplanar waveguide of the shorted stub circuit is λ/4. If the shorted stub circuit is shorted, point A is shorted (impedance 0), and transformed into open (impedance co) when the second-order harmonic wave 2f0 passes through λ/4 impedance. Then point B has a large impedance relative to the fundamental wave f0, the energy of the fundamental wave f0 cannot be leaked from point B to point A but transmitted to a subsequent load or leaked to point C.

The open stub circuit includes a microstrip line or a coplanar waveguide and the length of the microstrip line or the coplanar waveguide is also λ/4. Since it is open, point C is open (impedance co) and transformed into shorted (impedance value is very small) through λ/4 impedance. Likewise, the energy cannot be leaked to point C. That is, the energy of the fundamental wave f0 at point B cannot be leaked to point A and point C but transmitted to the load. Because the point B is both a load open point of 2f0 and a load short point of 2f0, the high efficiency output of the radio frequency power amplifier is achieved finally. It is noted that the energy of the fundamental wave f0 at point B cannot be leaked to point A and point C, but transmitted to the load and therefore the shorted stub circuit and the open stub circuit connected in parallel which are designed in the present invention have no impact on the transmission of the fundamental wave f0.

An embodiment of the present invention further provides an impedance matching method. In this method, matching is performed for an optimal efficiency load impedance of an envelope tracking power supply and a conjugate impedance of an optimal efficiency load impedance of a radio frequency power amplifier, so that the envelope tracking radio frequency power amplifier can obtain the optimal efficiency and the optimal efficiency load impedance of the envelope tracking power supply. The method includes the following steps.

At step a, the optimal efficiency load impedance and/or the conjugate impedance of the optimal efficiency load impedance of the radio frequency power amplifier is obtained according to the characteristics of the envelope tracking power supply and/or the radio frequency power amplifier.

At step b, the optimal efficiency of the envelope tracking radio frequency power amplifier is obtained by performing impedance matching according to the optimal efficiency load impedance of the envelope tracking power supply and the conjugate impedance of the optimal efficiency load impedance of the radio frequency power amplifier.

At step c, the designated load impedance is obtained by performing impedance matching according to the optimal efficiency load impedance of the envelope tracking power supply.

The optimal efficiency and the designated load impedance can be obtained by a method such as computer simulation, Smith chart calculation and old experiences in steps b and c.

At step d, a superimposed signal is output by superimposing other multi-order harmonic waves to the fundamental wave.

In the above technical solution, matching is performed based on the optimal efficiency load impedance of the envelope tracking power supply and the conjugate impedance of the optimal efficiency load impedance of the radio frequency power amplifier, so that the envelope tracking radio frequency power amplifier obtains the optimal efficiency. By superimposing the fundamental wave and the harmonic wave, the output power of the circuit is further improved, thereby satisfying the development requirements of signal transmission technology.

Finally, it is to be noted that the above embodiments are used only to describe the technical solutions of the present invention rather than limit the present invention. Although detailed descriptions are made to the present invention by referring to the preceding embodiments, those skilled in the art shall understand that they may make modification to the technical solutions recorded in the preceding embodiments or make equivalent substitution to partial technical features therein. Such modifications or substitutions will not deviate the essence of the corresponding technical solutions from the spirit and scope of the technical solutions of different embodiments of the present invention.

1. An impedance matching circuit, being applied to a power supply circuit of an envelope tracking radio frequency power amplifier, and comprising an envelope tracking power supply, a radio frequency power amplifier, a first matching circuit and a blocking capacitor, wherein
the envelope tracking power supply is configured to amplify an input envelope signal and supply a voltage and a current to the radio frequency power amplifier;
the first matching circuit comprises a first matching unit and a capacitor;
input ends of the first matching unit are connected with output ends of the envelope tracking power supply respectively, the output end is connected with one end of the blocking capacitor, the first matching circuit is located between the radio frequency power amplifier and the blocking capacitor, and an optimal efficiency of the envelope tracking radio frequency power amplifier is obtained by performing impedance matching according to an optimal efficiency load impedance of the envelope tracking power supply and a conjugate impedance of an optimal efficiency load impedance of the radio frequency power amplifier; and/or, the optimal efficiency of the envelope tracking radio frequency power amplifier is obtained by matching the optimal efficiency load impedance of the envelope tracking power supply according to a conjugate impedance of a load impedance value of the radio frequency power amplifier.

2. The impedance matching circuit according to claim 1, further comprising a third superimposing circuit, wherein,
the third superimposing circuit is configured to superimpose a fundamental wave and higher harmonic wave in a circuit to output a superimposed signal.

3. The impedance matching circuit according to claim 1, further comprising a second matching circuit comprising a second matching unit and a capacitor;
wherein the second matching circuit is configured to obtain a designated load impedance by performing impedance matching according to the optimal efficiency load impedance of the envelope tracking power supply.

4. The impedance matching circuit according to claim 3, wherein,
an input end of the second matching circuit is connected with the other end of the blocking capacitor to form a matching network with the blocking capacitor; and
the matching network is configured to obtain the designated load impedance by performing impedance matching according to the obtained optimal efficiency load impedance of the envelope tracking power supply.

5. The impedance matching circuit according to claim 3, wherein the first matching unit comprises microstrip lines or coplanar waveguides of different specifications;
the second matching unit further comprises microstrip lines or coplanar waveguides of different specifications; and
a length of the microstrip line depends on requirements of matching the optimal efficiency load impedance of the envelope tracking power supply to the designated load impedance.

6. The impedance matching circuit according to claim 2, wherein,
the third superimposing circuit comprises microstrip lines or coplanar waveguides of different lengths, the length of the microstrip line or the coplanar waveguide corresponds to a frequency of an output power of the radio frequency power amplifier.

7. An impedance matching method, being applied to a power supply circuit of an envelope tracking radio frequency power amplifier, wherein the method comprises:
obtaining an optimal efficiency of the envelope tracking radio frequency power amplifier by performing impedance matching according to an optimal efficiency load impedance of an envelope tracking power supply and a conjugate impedance of an optimal efficiency load impedance of a radio frequency power amplifier; and
obtaining a designated load impedance by performing impedance matching according to the obtained optimal efficiency load impedance of the envelope tracking power supply.

8. The impedance matching method according to claim 7, after the designated load impedance is obtained, further comprising:
superimposing a higher harmonic wave to a fundamental wave to output a superimposed signal.

9. The impedance matching method according to claim 7, before obtaining the optimal efficiency of the envelope tracking radio frequency power amplifier by performing impedance matching according to the optimal efficiency load impedance of the envelope tracking power supply and the conjugate impedance of the optimal efficiency load impedance of the radio frequency power amplifier, further comprising:
obtaining the optimal efficiency load impedance of the envelope tracking power supply and/or the conjugate impedance of the optimal efficiency load impedance of the radio frequency power amplifier according to the characteristics of the envelope tracking power supply and/or the radio frequency power amplifier.

10. The impedance matching method according to claim 7, wherein,
the method of calculating the optimal efficiency of the envelope tracking radio frequency power amplifier and the designated load impedance includes computer simulation, Smith chart calculation and old experiences.
